(19) United States
(12) Patent Application Publication
(10) Pub. No.: US 2024/0153886 A1
(43) Pub. Date: May 9, 2024

(54) SEMICONDUCTOR PACKAGE

(71) Applicant: Samsung Electronics Co., Ltd., Suwon-si (KR)

(72) Inventors: Haseob Seong, Suwon-si (KR); Seungduk Baek, Suwon-si (KR); Ae-Nee Jang, Suwon-si (KR)

(73) Assignee: Samsung Electronics Co., Ltd., Suwon-si (KR)

(21) Appl. No.: 18/225,447

(22) Filed: Jul. 24, 2023

(30) Foreign Application Priority Data
Nov. 7, 2022 (KR) 10-2022-0146898

(51) Int. Cl. H01L 23/00; H01L 23/31; H01L 23/48; H01L 25/065

(52) U.S. Cl. CPC H01L 23/562; H01L 23/3107; H01L 23/481; H01L 24/08; H01L 25/0657; H01L 2224/08146

(57) ABSTRACT

A semiconductor package includes a substrate including a substrate pad and plural vias, the substrate having a first trench on a top surface of the substrate, and a chip stack on the substrate that includes semiconductor chips. A chip pad of a first semiconductor chip, which is a lowermost one of the semiconductor chips, is bonded to the substrate pad of the substrate. The chip pad and the substrate pad are formed of a same metallic material. The first trench overlaps with a corner of the first semiconductor chip, when viewed in plan view.

### CROSS-REFERENCE TO RELATED APPLICATION

This application claims priority to Korean Patent Application No. 10-2022-0146898, filed on Nov. 7, 2022, in the Korean Intellectual Property Office, the disclosure of which being incorporated by reference herein in its entirety.

### BACKGROUND

The present disclosure relates to a semiconductor package and a method of fabricating the same, and in particular, to a stack-type semiconductor package, which may include a substrate and a plurality of semiconductor chips stacked thereon, and a method of fabricating the same.

With recent advances in the electronics industry, demand for high-performance, high-speed, and compact electronic components are increasing. To meet this demand, packaging technologies for mounting a plurality of semiconductor chips in a single package are being developed.

Recently, demand for portable electronic devices has been rapidly increasing in the market, and thus, it may be necessary to reduce sizes and weights of electronic components constituting the portable electronic devices. For this reduction, it is necessary to develop packaging technologies of reducing a size and a weight of each component and of integrating a plurality of individual components in a single package. As the number of stacked devices increases, various technical issues are occurring.

### SUMMARY

It is an aspect to provide a semiconductor package with improved structural stability and a method of fabricating the same.

It is another aspect to provide a method of reducing a failure in a process of fabricating a semiconductor package and a semiconductor package fabricated thereby.

According to an aspect of one or more example embodiments, a semiconductor package comprising a substrate comprising a substrate pad and a plurality of vias, the substrate having a first trench on a top surface of the substrate; and a chip stack on the substrate, the chip stack comprising a plurality of semiconductor chips, wherein a chip pad of a first semiconductor chip, which is a lowermost one of the plurality of semiconductor chips, is bonded to the substrate pad of the substrate, wherein the chip pad and the substrate pad are formed of a same metallic material, and wherein the first trench overlaps with a corner of the first semiconductor chip, when viewed in plan view.

According to another aspect of one or more example embodiments, a semiconductor package comprising a buffer chip; a first semiconductor chip on the buffer chip, a first pad of the buffer chip being bonded to a second pad of the first semiconductor chip, the first pad and the second pad being formed of a same metallic material; a second semiconductor chip on the first semiconductor chip, a third pad of the first semiconductor chip being bonded to a fourth pad of the second semiconductor chip, the third pad and the fourth pad being formed of a same metallic material; a mold layer on the buffer chip that encloses the first semiconductor chip and the second semiconductor chip; and a buffering structure interposed between the buffer chip and the first semiconductor chip, wherein the buffering structure overlaps with a corner of the first semiconductor chip, when viewed in plan view.

According to yet another aspect of one or more example embodiments, a semiconductor package comprising a semiconductor substrate comprising a plurality of vias; a plurality of semiconductor chips stacked on the semiconductor substrate; and a mold layer on the semiconductor substrate that encloses the plurality of semiconductor chips. The semiconductor substrate comprises a first trench in a top surface of the semiconductor substrate; and a first buffering structure in the first trench, wherein the first trench overlaps with a corner of a lowermost one of the plurality of semiconductor chips, when viewed in plan view, and wherein a rigidity of the first buffering structure is less than a rigidity of the semiconductor substrate.

### BRIEF DESCRIPTION OF DRAWINGS

FIG. 1 is a sectional view illustrating a semiconductor package according to some embodiments.

FIG. 2 is an enlarged view illustrating a portion ‘A’ of FIG. 1.

FIG. 3 is plan view illustrating a semiconductor package according to some embodiments.

FIGS. 4, 5, 6, 7, and 8 are enlarged views illustrating a portion ‘B’ of FIG. 3.

FIG. 9 is plan view illustrating a semiconductor package according to some embodiments.

FIG. 10 is a sectional view illustrating a semiconductor package according to some embodiments.

FIG. 11 is an enlarged view illustrating a portion ‘C’ of FIG. 10.

FIG. 12 is a sectional view illustrating a semiconductor package according to some embodiments.

FIG. 13 is an enlarged view illustrating a portion ‘D’ of FIG. 12.

FIG. 14 is a sectional view illustrating a semiconductor package according to some embodiments.

FIG. 15 is an enlarged view illustrating a portion ‘E’ of FIG. 14.

FIG. 16 is a sectional view illustrating a semiconductor package according to some embodiments.

FIG. 17 is an enlarged view illustrating a portion ‘F’ of FIG. 16.

FIG. 18 is a sectional view illustrating a semiconductor package according to some embodiments.

FIG. 19 is an enlarged view illustrating a portion ‘G’ of FIG. 18.

FIG. 20 is a sectional view illustrating a semiconductor package according to some embodiments.

FIG. 21 is an enlarged view illustrating a portion ‘H’ of FIG. 20.

FIG. 22 is a sectional view illustrating a semiconductor module according to some embodiments.

FIGS. 23, 24, 25, 26, 27, 28, 29, 30, and 31 are sectional views illustrating a method of fabricating a semiconductor package, according to some embodiments.

### DETAILED DESCRIPTION

Various example embodiments will now be described more fully with reference to the accompanying drawings, in which example embodiments are shown.

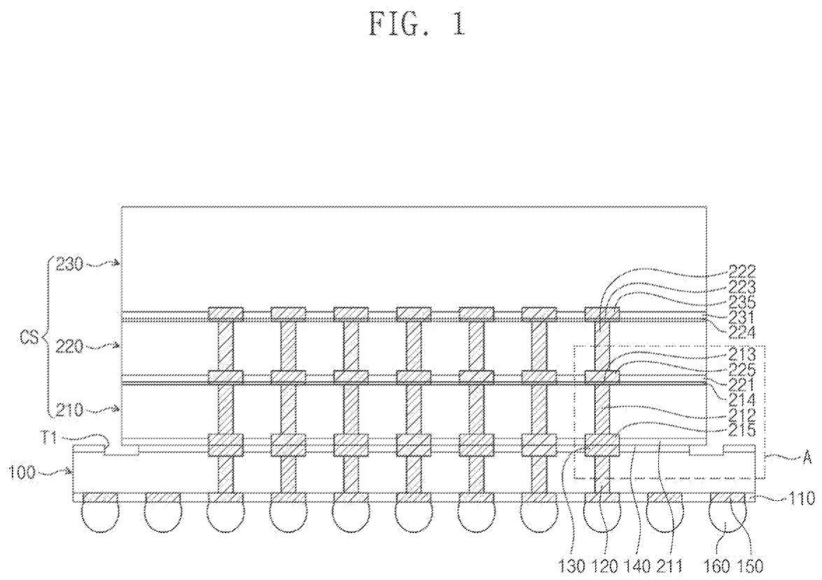

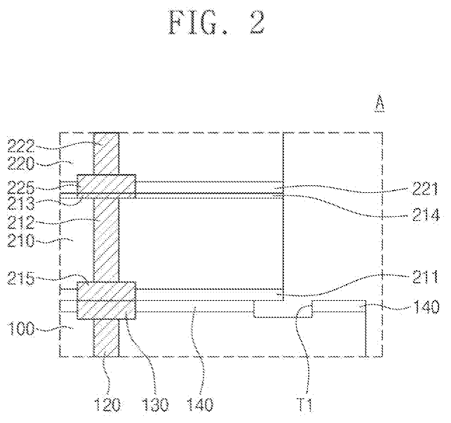

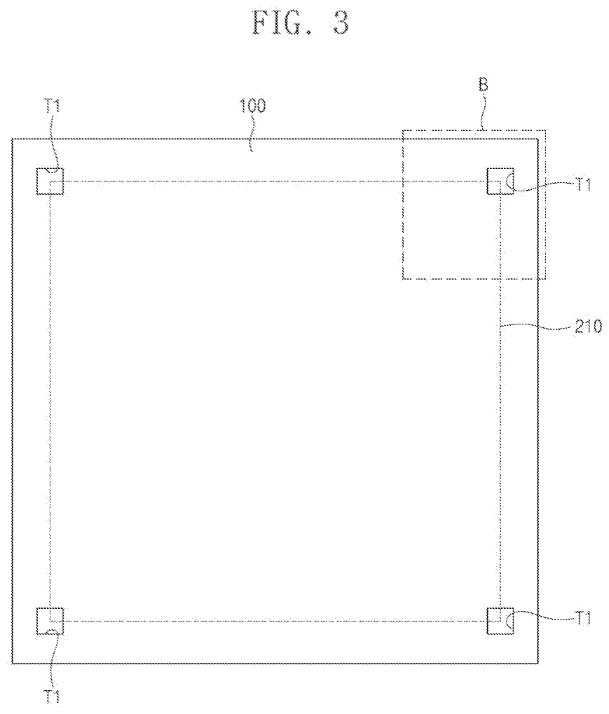

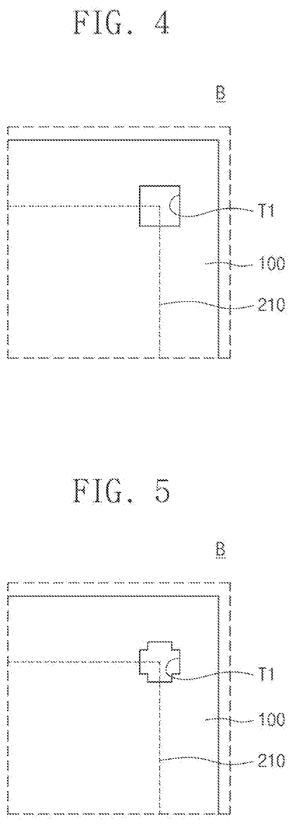

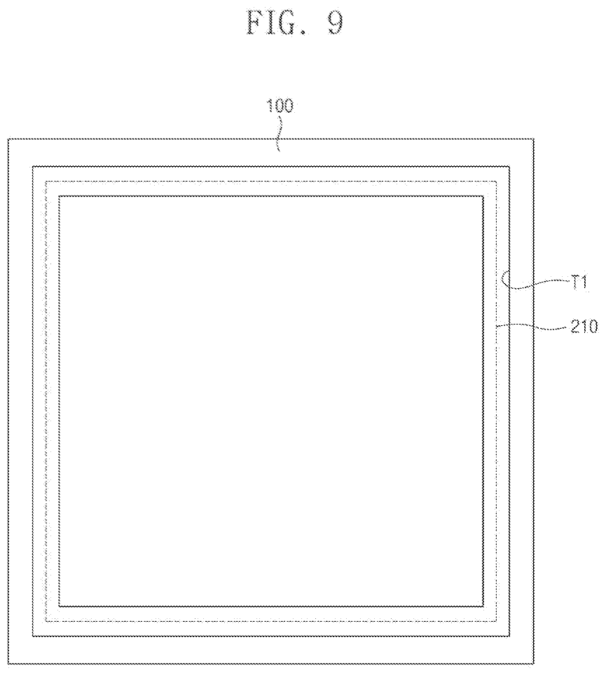

FIG. 1 is a sectional view illustrating a semiconductor package according to some embodiments. FIG. 2 is an enlarged view illustrating a portion ‘A’ of FIG. 1. FIG. 3 is plan view illustrating a semiconductor package according to some embodiments. FIGS. 4, 5, 6, 7, and 8 are enlarged views illustrating a portion ‘B’ of FIG. 3. FIG. 9 is plan view illustrating a semiconductor package according to some embodiments.

A semiconductor package according to some embodiments may be a stack-type package that is realized using via patterns. For example, semiconductor chips of the same kind may be stacked on a base substrate and may be electrically connected to each other through via patterns penetrating the same. The semiconductor chips may be coupled to each other using chip terminals, which are provided on bottom surfaces thereof.

Referring to FIGS. 1 and 2, in some embodiments, a base substrate may be provided. In some embodiments, the base substrate may be a semiconductor substrate. The base substrate may include an integrated circuit which is provided therein. In detail, in some embodiments, the base substrate may be referred to as a buffer semiconductor chip 100, which includes an electronic element (e.g., a transistor). For example, in some embodiments, the base substrate may be a wafer-level die formed of a semiconductor material (e.g., silicon (Si)). Although FIG. 1 illustrates an example in which the base substrate is the buffer semiconductor chip 100, embodiments are not limited to this example. In an embodiment, the base substrate may be a substrate (e.g., a printed circuit board (PCB)), in which an electronic element (e.g., a transistor) is not provided. A silicon wafer may be thinner than the printed circuit board (PCB). Hereinafter, the base substrate will be referred to as the buffer semiconductor chip 100.

The buffer semiconductor chip 100 may include a first circuit layer 110, a first via 120, a first rear pad 130, a first protection layer 140, and a first front pad 150.

The first circuit layer 110 may be provided on a bottom surface of the buffer semiconductor chip 100. The first circuit layer 110 may include the afore-described integrated circuit. For example, the first circuit layer 110 may be a memory circuit, a logic circuit, or combinations thereof. In other words, the bottom surface of the buffer semiconductor chip 100 may be an active surface. The first circuit layer 110 may include an electronic element (e.g., a transistor), an insulating pattern, and an interconnection pattern.

The first via 120 may be provided to vertically penetrate the buffer semiconductor chip 100. For example, the first via 120 may connect a top surface of the buffer semiconductor chip 100 to the first circuit layer 110. The first via 120 and the first circuit layer 110 may be electrically connected to each other. In an embodiment, a plurality of first vias 120 may be provided. In some embodiments, an insulating layer (not shown) may be provided to enclose the first via 120. For example, the insulating layer may be formed of or include at least one of silicon oxide (SiO), silicon nitride (SiN), silicon oxynitride (SiON), or low-k dielectric materials.

The first rear pad 130 may be disposed on the top surface of the buffer semiconductor chip 100. The first rear pad 130 may be coupled to the first via 120. In an embodiment, a plurality of first rear pads 130 may be provided. In this case, the first rear pads 130 may be coupled to a plurality of first vias 120, respectively, and the first rear pads 130 may be arranged in an arrangement corresponding to the arrangement of the first vias 120. The first rear pad 130 may be coupled to the first circuit layer 110 through the first via 120. The first rear pad 130 may be formed of or include at least one of various metallic materials (e.g., copper (Cu), aluminum (Al), and/or nickel (Ni)).

The first protection layer 140 may be disposed on the top surface of the buffer semiconductor chip 100 to enclose the first rear pad 130. The first protection layer 140 may expose the first rear pad 130. A top surface of the first protection layer 140 may be substantially flat and may be substantially coplanar with a top surface of the first rear pad 130. The buffer semiconductor chip 100 may be protected by the first protection layer 140. The first protection layer 140 may be formed of or include at least one of silicon oxide (SiO), silicon nitride (SiN), silicon oxynitride (SiON), or silicon carbon nitride (SiCN).

FIGS. 1 and 2 illustrate an example, in which the first rear pad 130 is provided to vertically penetrate the first protection layer 140 and is extended into the semiconductor layer of the buffer semiconductor chip 100 thereunder, but embodiments are not limited to this example. In some embodiments, a level of a bottom surface of the first rear pad 130 may be located at the same level as a level of a bottom surface of the first protection layer 140. In other words, in some embodiments, the bottom surface of the first rear pad 130 may be coplanar with the bottom surface of the first protection layer 140. For brevity's sake, the description that follows will refer to the embodiment of FIGS. 1 and 2.

The first front pad 150 may be disposed on the bottom surface of the buffer semiconductor chip 100. In more detail, the first front pad 150 may be exposed to the outside of the first circuit layer 110 on a bottom surface of the first circuit layer 110. A bottom surface of the first front pad 150 may be substantially flat and may be substantially coplanar with the bottom surface of the first circuit layer 110. The first front pad 150 may be electrically connected to the first circuit layer 110. In an embodiment, a plurality of first front pads 150 may be provided. The first front pad 150 may be formed of or include at least one of various metallic materials (e.g., copper (Cu), aluminum (Al), and/or nickel (Ni)).

Although not shown, in some embodiments, the buffer semiconductor chip 100 may further include a lower protection layer (not shown). The lower protection layer (not shown) may be disposed on the bottom surface of the buffer semiconductor chip 100 to cover the first circuit layer 110. The first circuit layer 110 may be protected by the lower protection layer (not shown). The lower protection layer (not shown) may expose the first front pad 150. The lower protection layer (not shown) may be formed of or include at least one of silicon oxide (SiO), silicon nitride (SiN), silicon oxynitride (SiON), or silicon carbon nitride (SiCN).

An outer terminal 160 may be provided on the bottom surface of the buffer semiconductor chip 100. The outer terminal 160 may be disposed on the first front pad 150. The outer terminal 160 may be electrically connected to the first circuit layer 110 and the first via 120. In an embodiment, the outer terminal 160 may be disposed below the first via 120. In this case, the first via 120 may be provided to penetrate the first circuit layer 110 and may be exposed to the outside of the first circuit layer 110 near the bottom surface of the first circuit layer 110, and the outer terminal 160 may be directly coupled to the first via 120. In an embodiment, a plurality of outer terminals 160 may be provided. In this case, the outer terminals 160 may be coupled to the first front pads 150, respectively. The outer terminal 160 may be formed of or include an alloy containing at least one of tin (Sn), silver (Ag), copper (Cu), nickel (Ni), bismuth (Bi), indium (In), antimony (Sb), or cerium (Ce).

FIG. 1 illustrates an example in which the first circuit layer 110 is provided on the bottom surface of the buffer semiconductor chip 100, but embodiments are not limited to this example. In an embodiment, the first circuit layer 110 may be provided on the top surface of the buffer semiconductor chip 100.

Referring further to FIGS. 1 and 2, the buffer semiconductor chip 100 may include at least one first trench T1. A structure of the first trench T1, in conjunction with a lower semiconductor chip 210, will be described in more detail below.

A chip stack CS may be disposed on the buffer semiconductor chip 100. The chip stack CS may include a plurality of semiconductor chips 210, 220, and 230. In some embodiments, the semiconductor chips 210, 220, and 230 may be of the same kind. For example, the semiconductor chips 210, 220, and 230 may be memory chips. The chip stack CS may include the lower semiconductor chip 210, which is directly connected to the buffer semiconductor chip 100, at least one intermediate semiconductor chip 220 stacked on the lower semiconductor chip 210, and an upper semiconductor chip 230 disposed on the intermediate semiconductor chip 220. The lower semiconductor chip 210, the intermediate semiconductor chip 220, and the upper semiconductor chip 230 may be sequentially stacked on the buffer semiconductor chip 100. In some cases, the lower semiconductor chip 210 may also be referred to as a lowermost semiconductor chip 230 of the chip stack CS.

The lower semiconductor chip 210 may include a second circuit layer 211 facing the buffer semiconductor chip 100. The second circuit layer 211 may be provided on a bottom surface of the lower semiconductor chip 210. The second circuit layer 211 may include the afore-described integrated circuit. For example, the second circuit layer 211 may include a memory circuit. In other words, the bottom surface of the lower semiconductor chip 210 may be an active surface. The second circuit layer 211 may include an electronic element (e.g., a transistor), an insulating pattern, and an interconnection pattern.

The lower semiconductor chip 210 may include a second protection layer 214, which is provided opposite to the second circuit layer 211. The second protection layer 214 may be provided on a top surface of the lower semiconductor chip 210. The second protection layer 214 may protect the lower semiconductor chip 210. The second protection layer 214 may be formed of or include at least one of silicon oxide (SiO), silicon nitride (SiN), silicon oxynitride (SiON), or silicon carbon nitride (SiCN).

The lower semiconductor chip 210 may include a second via 212, which is provided to penetrate a portion of the lower semiconductor chip 210 in a direction from the second protection layer 214 toward the second circuit layer 211. In an embodiment, a plurality of second vias 212 may be provided. In some embodiments, an insulating layer (not shown) may be provided to enclose the second via 212. For example, the insulating layer may be formed of or include at least one of silicon oxide (SiO), silicon nitride (SiN), silicon oxynitride (SiON), or low-k dielectric materials. The second via 212 may be electrically connected to the second circuit layer 211.

A second rear pad 213 may be disposed in the second protection layer 214. A top surface of the second rear pad 213 may be exposed by the second protection layer 214. A top surface of the second protection layer 214 may be substantially flat and may be substantially coplanar with the top surface of the second rear pad 213. The second rear pad 213 may be connected to the second via 212. A second front pad 215 may be disposed on the second circuit layer 211. In more detail, the second front pad 215 may be exposed to the outside of the second circuit layer 211 near a bottom surface of the second circuit layer 211. A bottom surface of the second front pad 215 may be substantially flat and may be substantially coplanar with the bottom surface of the second circuit layer 211. The second front pad 215 may be coupled to the second circuit layer 211. The second rear pad 213 and the second front pad 215 may be electrically connected to the second circuit layer 211 by the second via 212. In an embodiment, a plurality of second rear pads 213 and a plurality of second front pads 215 may be provided. The second rear pad 213 and the second front pad 215 may be formed of or include at least one of various metallic materials (e.g., copper (Cu), aluminum (Al), and/or nickel (Ni)).

The lower semiconductor chip 210 may be mounted on the buffer semiconductor chip 100. In more detail, the lower semiconductor chip 210 may be disposed on the buffer semiconductor chip 100. The lower semiconductor chip 210 may be disposed on the buffer semiconductor chip 100 in a face down manner. The first rear pad 130 of the buffer semiconductor chip 100 may be vertically aligned to the second front pad 215 of the lower semiconductor chip 210. The buffer semiconductor chip 100 and the lower semiconductor chip 210 may be in contact with each other such that the first rear pad 130 is connected to the second front pad 215.

The lower semiconductor chip 210 may be connected to the buffer semiconductor chip 100. For example, the lower semiconductor chip 210 and the buffer semiconductor chip 100 may be in contact with each other. At an interface between the lower semiconductor chip 210 and the buffer semiconductor chip 100, the first rear pad 130 of the buffer semiconductor chip 100 may be bonded to the second front pad 215 of the lower semiconductor chip 210. Here, the first rear pad 130 and the second front pad 215 may form an inter-metal hybrid bonding structure. In the present specification, the hybrid bonding structure may mean a bonding structure which is formed by two materials, which are of the same kind and are fused at an interface therebetween. For example, the first rear pad 130 and the second front pad 215, which are bonded to each other, may have a continuous structure, and there may be no visible interface between the first rear pad 130 and the second front pad 215. For example, the first rear pad 130 and the second front pad 215 may be formed of the same material, and in this case, after bonding there may be no interface between the first rear pad 130 and the second front pad 215. In other words, the first rear pad 130 and the second front pad 215 may be provided as a single element. For example, the first rear pad 130 and the second front pad 215 may be bonded to each other such that, after bonding, the first rear pad 130 and the second front pad 215 constitute a single object.

At an interface between the buffer semiconductor chip 100 and the lower semiconductor chip 210, the first protection layer 140 of the buffer semiconductor chip 100 may be bonded to an insulating pattern of the second circuit layer 211 of the lower semiconductor chip 210. Here, the first protection layer 140 and the insulating pattern of the second circuit layer 211 may form a hybrid bonding structure of oxide, nitride, or oxynitride. For example, the first protection layer 140 and the insulating pattern of the second circuit layer 211 may be formed of the same material, and in this case, there may be no interface between the first protection layer 140 and the insulating pattern of the second circuit layer 211. In other words, the first protection layer 140 and the insulating pattern of the second circuit layer 211 may be bonded to each other such that, after bonding, the first protection layer 140 and the insulating pattern of the second circuit layer 211 form a single object. However, embodiments are not limited to this example. The first protection layer 140 and the insulating pattern of the second circuit layer 211 may be formed of different materials and may not have a continuous structure, and in this case, there may be a visible interface between the first protection layer 140 and the insulating pattern of the second circuit layer 211.

The intermediate semiconductor chip 220 may have substantially the same structure as the lower semiconductor chip 210. For example, the intermediate semiconductor chip 220 may include a third circuit layer 221 facing the buffer semiconductor chip 100, a third protection layer 224 opposite to the third circuit layer 221, a third via 222 penetrating the intermediate semiconductor chip 220 in a direction from the third protection layer 224 toward the third circuit layer 221, a third rear pad 223 in the third protection layer 224, and a third front pad 225 on the third circuit layer 221. The third circuit layer 221 and the third front pad 225 may be provided on a bottom surface of the intermediate semiconductor chip 220, which is an active surface of the intermediate semiconductor chip 220. The third protection layer 224 and the third rear pad 223 may be provided on a top surface of the intermediate semiconductor chip 220.

The upper semiconductor chip 230 may have a structure that is substantially similar to the lower semiconductor chip 210. For example, the upper semiconductor chip 230 may include a fourth circuit layer 231 facing the buffer semiconductor chip 100 and a fourth front pad 235 on the fourth circuit layer 231. The upper semiconductor chip 230 may not have a via pattern, a rear pad, and an upper protection layer. However, embodiments are not limited to this example. In an embodiment, the upper semiconductor chip 230 may include at least one of the via pattern, the rear pad, and the upper protection layer. The fourth circuit layer 231 and the fourth front pad 235 may be provided on a bottom surface of the upper semiconductor chip 230, and the bottom surface of the upper semiconductor chip 230 may be an active surface. The upper semiconductor chip 230 may have a thickness that is larger than the lower and intermediate semiconductor chips 210 and 220.

The intermediate semiconductor chip 220 may be mounted on the lower semiconductor chip 210. The second rear pad 213 of the lower semiconductor chip 210 may be vertically aligned to the third front pad 225 of the intermediate semiconductor chip 220. The intermediate semiconductor chip 220 and the lower semiconductor chip 210 may be in contact with each other such that the second rear pad 213 and the third front pad 225 are connected to each other.

The upper semiconductor chip 230 may be mounted on the intermediate semiconductor chip 220. The third rear pad 223 of the intermediate semiconductor chip 220 may be vertically aligned to may be vertically aligned to the fourth front pad 235 of the upper semiconductor chip 230. The upper semiconductor chip 230 and the intermediate semiconductor chip 220 may be in contact with each other such that the third rear pad 223 is connected to the fourth front pad 235.

A mounting structure of the intermediate and upper semiconductor chips 220 and 230 may be substantially the same as or similar to a structure, in which the lower semiconductor chip 210 is mounted on the buffer semiconductor chip 100.

The intermediate semiconductor chip 220 may be in contact with the lower semiconductor chip 210. At an interface between the intermediate semiconductor chip 220 and the lower semiconductor chip 210, the second rear pad 213 of the lower semiconductor chip 210 may be bonded to the third front pad 225 of the intermediate semiconductor chip 220. Here, the second rear pad 213 and the third front pad 225 may form an inter-metal hybrid bonding structure. At the interface between the intermediate semiconductor chip 220 and the lower semiconductor chip 210, the second protection layer 214 of the lower semiconductor chip 210 may be bonded to an insulating pattern of the third circuit layer 221 of the intermediate semiconductor chip 220. Here, the second protection layer 214 and the insulating pattern of the third circuit layer 221 may form a hybrid bonding structure of oxide, nitride, oxynitride, or carbon nitride.

The upper semiconductor chip 230 and the intermediate semiconductor chip 220 may be in contact with each other. At an interface between the upper semiconductor chip 230 and the intermediate semiconductor chip 220, the third rear pad 223 of the intermediate semiconductor chip 220 may be bonded to the fourth front pad 235 of the upper semiconductor chip 230. Here, the third rear pad 223 and the fourth front pad 235 may form an inter-metal hybrid bonding structure. At the interface of the upper and intermediate semiconductor chips 230 and 220, the third protection layer 224 of the intermediate semiconductor chip 220 may be bonded to an insulating pattern of the fourth circuit layer 231 of the upper semiconductor chip 230. Here, the third protection layer 224 and the insulating pattern of the fourth circuit layer 231 may form a hybrid bonding structure of oxide, nitride, oxynitride, or carbon nitride.

FIG. 1 illustrates an example, in which one intermediate semiconductor chip 220 is provided between the lower semiconductor chip 210 and the upper semiconductor chip 230, but embodiments are not limited to this example. For example, at least two or more intermediate semiconductor chips 220 may be provided between the lower semiconductor chip 210 and the upper semiconductor chip 230. Here, the intermediate semiconductor chips 220 may be bonded to each other in a hybrid bonding manner.

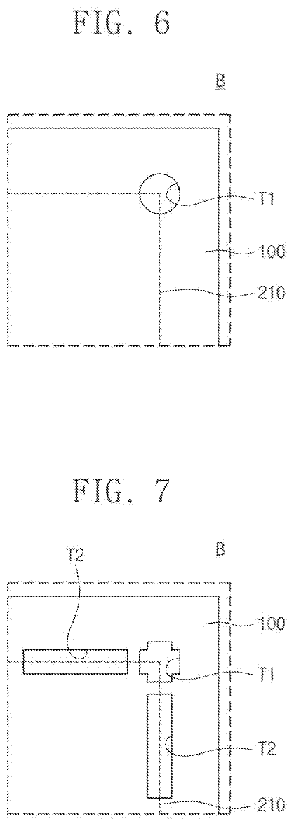

Referring further to FIGS. 1, 2, and 3, the buffer semiconductor chip 100 may include at least one first trench T1. The first trench T1 may be provided in the top surface of the buffer semiconductor chip 100. The first trench T1 may be extended from the top surface of the buffer semiconductor chip 100 toward the bottom surface of the buffer semiconductor chip 100. Here, a level of a bottom surface of the first trench T1 may be located at the same level as a level of the bottom surface of the first rear pad 130. However, embodiments are not limited to this example, and in an embodiment, the bottom surface of the first trench T1 may be located at a level, which is higher or lower than the bottom surface of the first rear pad 130. As shown in FIG. 3, when viewed in plan view, the first trench T1 may be overlapped with one of corners of the lower semiconductor chip 210. Here, the corner may be a part of the lower semiconductor chip 210, which is formed by two adjacent side surfaces of the lower semiconductor chip 210. In an embodiment, a plurality of first trenches T1 may be provided, and each of the first trenches T1 may be placed below a corresponding one of the plurality of corners of the lower semiconductor chip 210. In more detail, when viewed in plan view, a portion of the first trench T1 may be placed below the lower semiconductor chip 210 to be vertically overlapped with the lower semiconductor chip 210, and another portion of the first trench T1 may be placed around the lower semiconductor chip 210 and may not be vertically overlapped with the lower semiconductor chip 210. Here, each of the corners of the lower semiconductor chip 210 may be placed on a center of the first trench T1. In an embodiment, as shown in FIG. 4, the first trench T1 may have a rectangular or square shape, when viewed in plan view. In some embodiments, as shown in FIG. 5, the first trench T1 may have a cross shaped region, which is composed of two portions extended parallel to first and second side surfaces of the lower semiconductor chip 210 in contact with the corner of the lower semiconductor chip 210, when viewed in plan view. In an embodiment, as shown in FIG. 6, the first trench T1 may have a circular shape, when viewed in plan view. Although not shown, the first trench T1 may have one of polygonal shapes, when viewed in plan view.

The semiconductor chips 210, 220, and 230 may be vertically stacked on the buffer semiconductor chip 100. In an embodiment, the buffer semiconductor chip 100 and the semiconductor chips 210, 220, and 230 may be directly bonded to each other. Thus, each of the semiconductor chips 210, 220, and 230 may exert a weight (i.e., gravity multiplied by mass) on another chip thereunder, and thus, the chip stack may exert a strong pressure on the buffer semiconductor chip 100 such that the lowermost one (i.e., 210) of the lower semiconductor chips, may exert the strongest pressure on the buffer semiconductor chip 100. Here, the semiconductor chips 210, 220, and 230 may be bent by heat, which is generated when the semiconductor package is operated or generated in a process of fabricating the semiconductor package, and in this case, depending on the warpage types (e.g., smile warpage or crying warpage) of the semiconductor chips 210, 220, and 230, as a distance to edge regions of the semiconductor chips 210, 220, and 230 decreases, a stress exerted between the semiconductor chips 210, 220, and 230 may increase. Thus, in a region between the buffer semiconductor chip 100 and the lower semiconductor chip 210, a stress exerted on the buffer semiconductor chip 100 may be strongest at an edge portion (in particular, the corner) of the lower semiconductor chip 210.

According to some embodiments, the first trench T1 may be overlapped with the corner of the lower semiconductor chip 210 and may be provided in the top surface of the buffer semiconductor chip 100. The corner of the lower semiconductor chip 210 may be spaced apart from the buffer semiconductor chip 100 by the first trench T1. Thus, it may be possible to prevent the buffer semiconductor chip 100 from being damaged by a stress, which is exerted by the chip stack, in particular, the lower semiconductor chip 210. In other words, it may be possible to improve structural stability of the semiconductor package.

In the description of the embodiments to be explained below, an element previously described with reference to FIGS. 1, 2, 3, 4, 5, and 6 may be identified by the same reference number without repeating an overlapping description thereof, for concise description.

FIG. 7 is an enlarged view illustrating a portion ‘B’ of FIG. 3.

Referring to FIGS. 1, 2, and 7, the buffer semiconductor chip 100 may further include at least one second trench T2, in addition to the first trench T1. The second trench T2 may be provided in the top surface of the buffer semiconductor chip 100. The second trench T2 may be extended from the top surface of the buffer semiconductor chip 100 toward the bottom surface of the buffer semiconductor chip 100. Here, a level of a bottom surface of the second trench T2 may be located at the same level as the level of the bottom surface of the first rear pad 130. However, embodiments are not limited to this example, and in an embodiment, the bottom surface of the second trench T2 may be located at a level, which is higher or lower than the bottom surface of the first rear pad 130. As shown in FIG. 7, the second trench T2 may be adjacent to one of the corners of the lower semiconductor chip 210, when viewed in plan view. Here, the second trench T2 may be disposed to be spaced apart from the first trench T1. The second trench T2 may extend along a side surface in contact with the corner of the lower semiconductor chip 210. The second trench T2 overlap with the side surface of the lower semiconductor chip 210. In more detail, when viewed in plan view, a portion of the second trench T2 may be placed below the lower semiconductor chip 210 and may vertically overlap with the lower semiconductor chip 210, and another portion of the second trench T2 may be placed at a side of the lower semiconductor chip 210 and may not vertically overlap with the lower semiconductor chip 210. Here, the side surface of the lower semiconductor chip 210 may cross the second trench T2. As shown in FIG. 7, the second trench T2 may be a line-shaped region, which is extended along the side surface of the lower semiconductor chip 210. In an embodiment, a plurality of second trenches T2 may be provided, and each of the second trenches T2 may extend from the corner of the lower semiconductor chip 210 along one of the side surfaces of the lower semiconductor chip 210 that are adjacent to the corner.

In the region between the buffer semiconductor chip 100 and the lower semiconductor chip 210, a stress exerted on the buffer semiconductor chip 100 may be strongest at the corner of the lower semiconductor chip 210 and may also be strong at a region below the side surface (i.e., along an edge) of the lower semiconductor chip 210.

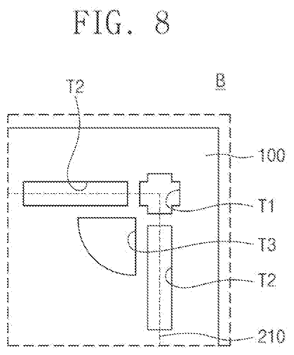

According to some embodiments, the first trench T1 and the second trench T2, which are respectively overlapped with the corner and the side surface of the lower semiconductor chip 210, may be provided in the top surface of the buffer semiconductor chip 100. The corner and the side surface of the lower semiconductor chip 210 may be spaced apart from the buffer semiconductor chip 100 by the first and second trenches T1 and T2. Thus, it may be possible to prevent the buffer semiconductor chip 100 from being damaged by a stress, which is exerted by the chip stack, in particular, the lower semiconductor chip 210. In other words, it may be possible to improve the structural stability of the semiconductor package. FIG. 8 is an enlarged view illustrating the portion ‘B’ of FIG. 3.

Referring to FIGS. 1, 2, and 8, the buffer semiconductor chip 100 may further include at least one third trench T3, in addition to the first and second trenches T1 and T2. The third trench T3 may be provided in the top surface of the buffer semiconductor chip 100. The third trench T3 may be extended from the top surface of the buffer semiconductor chip 100 toward the bottom surface of the buffer semiconductor chip 100. Here, a level of a bottom surface of the third trench T3 may be located at the same level as the level of the bottom surface of the first rear pad 130. However, embodiments are not limited to this example, and the bottom surface of the third trench T3 may be located at a level, which is higher or lower than the bottom surface of the first rear pad 130. As shown in FIG. 8, when viewed in plan view, the third trench T3 may be adjacent to one of the corners of the lower semiconductor chip 210. Here, the third trench T3 may be spaced apart from the first and second trenches T1 and T2. The third trench T3 may be adjacent to the corner of the lower semiconductor chip 210 but may be spaced apart from a side surface of the lower semiconductor chip 210 in contact with the corner. The entirety of the third trench T3 may be overlapped with the lower semiconductor chip 210. In more detail, when viewed in plan view, the entirety of the third trench T3 may be placed below the lower semiconductor chip 210 and may be vertically overlapped with the lower semiconductor chip 210. As shown in FIG. 8, the third trench T3 may have a fan shape having a base adjacent to the corner of the lower semiconductor chip, or may have triangle shape whose vertex is adjacent to the corner of the lower semiconductor chip 210, when viewed in plan view. The third trench T3 may be disposed on a corner region that is adjacent to the corner of the lower semiconductor chip 210. The corner region may be a region, which is located around or near the corner of the lower semiconductor chip 210 and has a width ranging from 1 μm to 100 μm. In an embodiment, a plurality of third trenches T3 may be provided, and each of the third trenches T3 may be disposed to be adjacent to a corresponding one of the plurality of corners of the lower semiconductor chip 210.

FIG. 8 illustrates an example, in which all of the first, second, and third trenches T1, T2, and T3 are provided on the buffer semiconductor chip 100, but embodiments are not limited to this example. In some embodiments, the first trench T1 and the third trench T3 may be provided on the buffer semiconductor chip 100, and the second trench T2 may be omitted on the buffer semiconductor chip 100.

FIG. 9 is an enlarged view illustrating the portion ‘B’ of FIG. 3.

Referring to FIGS. 1, 2, and 9, the first trench T1 may extend from one of the corners of the lower semiconductor chip 210 to another one of the corners of the lower semiconductor chip 210, which is adjacent thereto, along one side surface of the lower semiconductor chip 210. As an example, the first trench T1 may extend along the side surfaces of the lower semiconductor chip 210 to enclose the lower semiconductor chip 210. When viewed in plan view, the first trench T1 may have a ring shape. Here, a portion of the first trench T1 may be placed below the lower semiconductor chip 210 and may vertically overlap with the lower semiconductor chip 210, and another portion of the first trench T1 may be placed at a side of the lower semiconductor chip 210 and may not vertically overlap with the lower semiconductor chip 210. Here, the side surfaces of the lower semiconductor chip 210 may be located on the first trench T1.

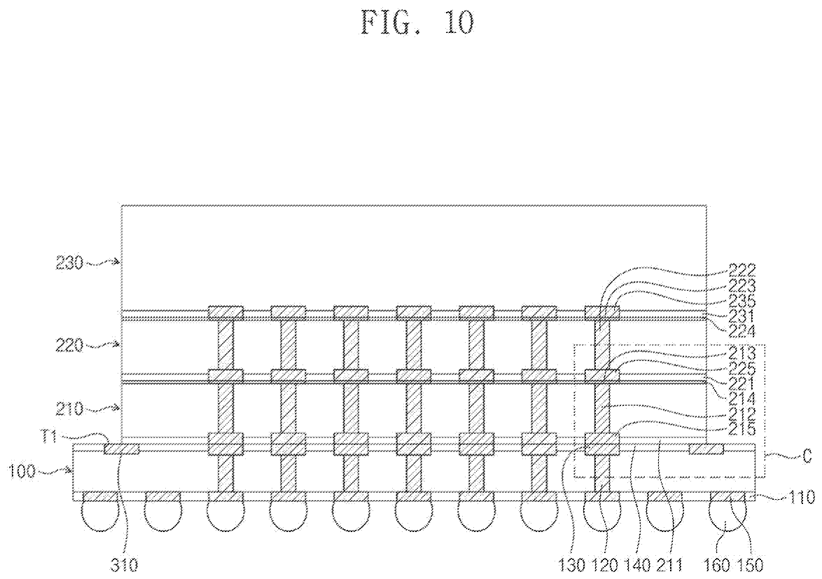

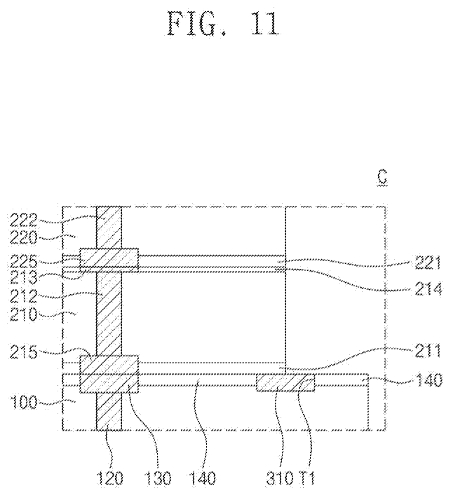

FIG. 10 is a sectional view illustrating a semiconductor package according to some embodiments. FIG. 11 is an enlarged view illustrating a portion ‘C’ of FIG. 10.

Referring to FIGS. 10 and 11, the buffer semiconductor chip 100 may further include a first buffering structure 310 provided in the first trench T1. The first buffering structure 310 may be provided to completely fill an inner space of the first trench T1. A top surface of the first buffering structure 310 may be substantially flat and may be substantially coplanar with the top surface of the buffer semiconductor chip 100 (i.e., the top surface of the first protection layer 140). The first buffering structure 310 may be provided at the same level as the first rear pad 130. For example, a level of the top surface of the first buffering structure 310 may be located at the same level as a level of the top surface of the first rear pad 130. In other words, the top surface of the first buffering structure may be coplanar with the top surface of the first rear pad 130. A thickness of the first buffering structure 310 may be equal to a thickness of the first rear pad 130. However, embodiments are not limited to this example, and the position and thickness of the first buffering structure 310 may be variously changed. In the case where a plurality of first trenches T1 are provided, a plurality of first buffering structures 310 may be provided, and each of the first buffering structures 310 may fill a corresponding one of the first trenches T1. However, embodiments are not limited to this and, in some embodiments, only a portion of the first trenches T1 may be provided with the first buffering structures 310. The first buffering structure 310 may be formed of or include a highly-deformable material. The first buffering structure 310 may be formed of or include at least one of metallic materials. For example, the first buffering structure 310 may be formed of or include at least one of various metallic materials (e.g., copper (Cu), aluminum (Al), and/or nickel (Ni)). The first buffering structure 310 may be formed of or include the same material as the first rear pad 130. However, embodiments are not limited to this example.

According to some embodiments, the first buffering structure 310 may absorb a stress exerted on the buffer semiconductor chip 100 by the corner of the lower semiconductor chip 210. In more detail, the first buffering structure 310 may be provided to support the corner of the lower semiconductor chip 210, and here, the first buffering structure 310 may not be broken by a pressure or stress, which is exerted by the corner of the lower semiconductor chip 210, although the first buffering structure 310 may be deformed. Thus, a pressure or stress from the corner of the lower semiconductor chip 210 may be absorbed by the first buffering structure 310 and may not be transferred to the semiconductor layer of the buffer semiconductor chip 100. In other words, the semiconductor layer of the buffer semiconductor chip 100 may not be broken or damaged. In addition, the corner of the lower semiconductor chip 210 may be supported by the first buffering structure 310. Accordingly, it may be possible to realize a semiconductor package with improved structural stability.

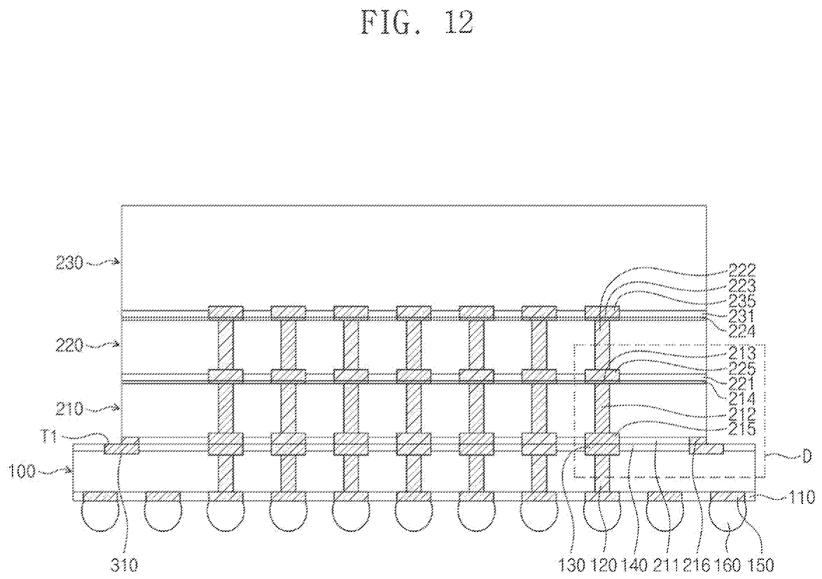

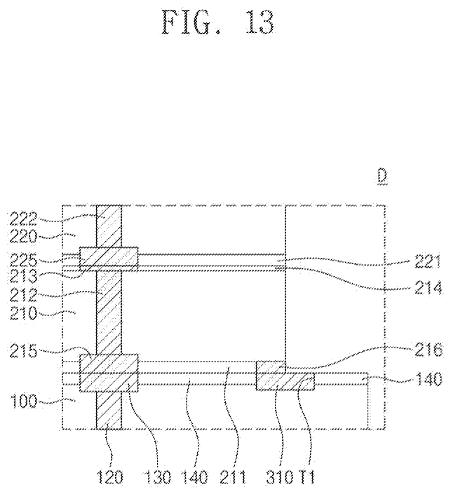

FIG. 12 is a sectional view illustrating a semiconductor package according to some embodiments. FIG. 13 is an enlarged view illustrating a portion ‘D’ of FIG. 12.

Referring to FIGS. 12 and 13, the lower semiconductor chip 210 may further include a dummy pad 216, when compared with the semiconductor package of FIGS. 10 and 11.

The dummy pad 216 may be disposed on the second circuit layer 211. In more detail, the dummy pad 216 may be exposed to the outside of the second circuit layer 211 near the bottom surface of the second circuit layer 211. A bottom surface of the dummy pad 216 may be substantially flat and may be substantially coplanar with the bottom surface of the second circuit layer 211. The dummy pad 216 may be electrically disconnected from the integrated circuit of the second circuit layer 211. In an embodiment, a plurality of dummy pads 216 may be provided. The dummy pads 216 may be disposed on the corners of the lower semiconductor chips 210. For example, the dummy pads 216 may be provided at positions corresponding to the first buffering structures 310. The dummy pad 216 may be formed of or include at least one of various metallic materials (e.g., copper (Cu), aluminum (Al), and/or nickel (Ni)).

The lower semiconductor chip 210 may be mounted on the buffer semiconductor chip 100. In more detail, the lower semiconductor chip 210 may be disposed on the buffer semiconductor chip 100. The lower semiconductor chip 210 may be disposed on the buffer semiconductor chip 100 in a face down manner. The first rear pad 130 of the buffer semiconductor chip 100 may be vertically aligned to the second front pad 215 of the lower semiconductor chip 210, and the first buffering structure 310 of the buffer semiconductor chip 100 may be vertically aligned to the dummy pad 216 of the lower semiconductor chip 210. The buffer semiconductor chip 100 and the lower semiconductor chip 210 may be in contact with each other such that the first rear pad 130 is connected to the second front pad 215 and the first buffering structure 310 is connected to the dummy pad 216.

The lower semiconductor chip 210 may be connected to the buffer semiconductor chip 100. At an interface between the lower semiconductor chip 210 and the buffer semiconductor chip 100, the first rear pad 130 of the buffer semiconductor chip 100 may be bonded to the second front pad 215 of the lower semiconductor chip 210. Here, the first rear pad 130 and the second front pad 215 may form an inter-metal hybrid bonding structure. At the interface between the lower semiconductor chip 210 and the buffer semiconductor chip 100, the first buffering structure 310 of the buffer semiconductor chip 100 may be bonded to the dummy pad 216 of the lower semiconductor chip 210. Here, the first buffering structure 310 and the dummy pad 216 may form an inter-metal hybrid bonding structure. For example, the first buffering structure 310 and the dummy pad 216, which are bonded to each other, may have a continuous structure, and there may be no visible interface between the first buffering structure 310 and the dummy pad 216. For example, the first buffering structure 310 and the dummy pad 216 may be formed of the same material, and in this case, there may be no interface between the first buffering structure 310 and the dummy pad 216. In other words, the first buffering structure 310 and the dummy pad 216 may be provided as a single element. For example, the first buffering structure 310 and the dummy pad 216 may be bonded to each other such that, after bonding, the first buffering structure 310 and the dummy pad 216 form a single object.

According to some embodiments, the first buffering structure 310 of the buffer semiconductor chip 100 may be bonded to the dummy pad 216 of the lower semiconductor chip 210. Thus, the lower semiconductor chip 210 may be more robustly bonded to the buffer semiconductor chip 100, and this may make it possible to realize a semiconductor package with improved structural stability.

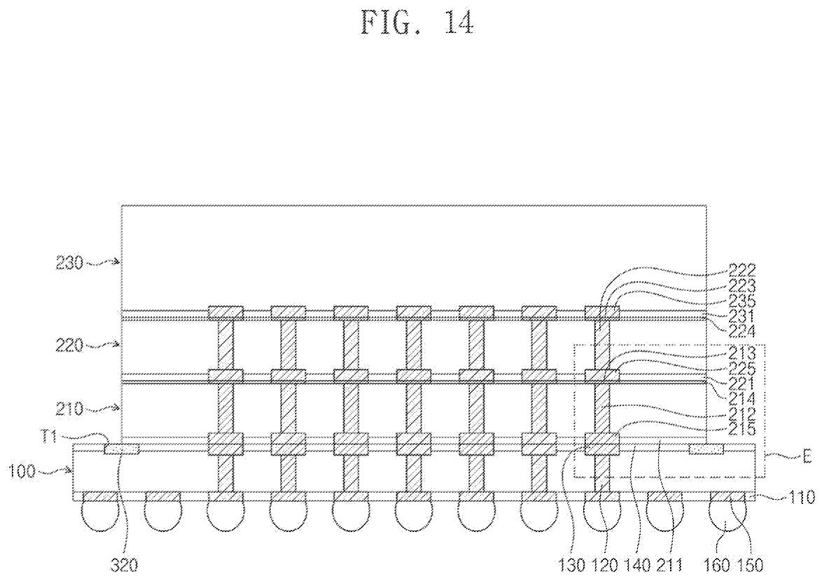

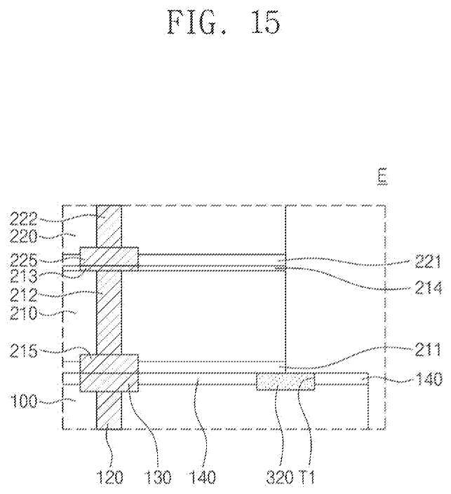

FIG. 14 is a sectional view illustrating a semiconductor package according to some embodiments. FIG. 15 is an enlarged view illustrating a portion ‘E’ of FIG. 14.

Referring to FIG. 14, the buffer semiconductor chip 100 may further include a second buffering structure 320 provided in the first trench T1. The second buffering structure 320 may be provided to fully fill an inner space of the first trench T1. A top surface of the second buffering structure 320 may be substantially flat and may be substantially coplanar with the top surface of the buffer semiconductor chip 100 (i.e., the top surface of the first protection layer 140). The second buffering structure 320 may be provided at the same level as the first rear pad 130. For example, a level of the top surface of the second buffering structure 320 may be located at the same level as the level of the top surface of the first rear pad 130. A thickness of the second buffering structure 320 may be equal to the thickness of the first rear pad 130. However, embodiments are not limited to this example, and the position and thickness of the second buffering structure 320 may be variously changed. In the case where a plurality of first trenches T1 are provided, a plurality of second buffering structures 320 may be provided, and in this case, each of the second buffering structures 320 may be provided to fill a corresponding one of the first trenches T1. The second buffering structure 320 may be formed of or include a material with low rigidity. For example, the rigidity of the second buffering structure 320 may be less than the rigidity of the semiconductor layer of the buffer semiconductor chip 100. The second buffering structure 320 may include an insulating polymer. For example, the second buffering structure 320 may include an under-filling material.

According to some embodiments, the second buffering structure 320 may absorb a stress, which is exerted on the buffer semiconductor chip 100 from the corner of the lower semiconductor chip 210. Thus, a pressure or stress from the corner of the lower semiconductor chip 210 may be absorbed by the second buffering structure 320 and may not be transferred to the semiconductor layer of the buffer semiconductor chip 100. In other words, the semiconductor layer of the buffer semiconductor chip 100 may not be broken or damaged. Accordingly, it may be possible to improve the structural stability of the semiconductor package.

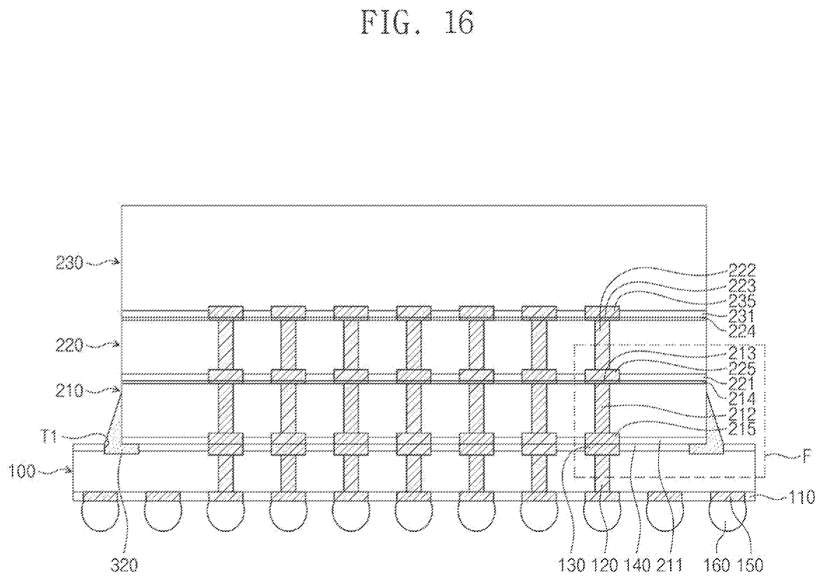

FIG. 16 is a sectional view illustrating a semiconductor package according to some embodiments. FIG. 17 is an enlarged view illustrating a portion ‘F’ of FIG. 16.

Referring to FIGS. 16 and 17, the second buffering structure 320 may have an extended portion 322, unlike the semiconductor package of FIGS. 14 and 15. The extended portion 322 may be extended from the top surface of the second buffering structure 320 to cover the side surface of the lower semiconductor chip 210. In other words, the second buffering structure 320 may extend from a region in the first trench T1 to another region on the side surface of the lower semiconductor chip 210.

According to some embodiments, the side surface of the lower semiconductor chip 210 may be protected by the second buffering structure 320. Accordingly, it may be possible to improve the structural stability of the semiconductor package.

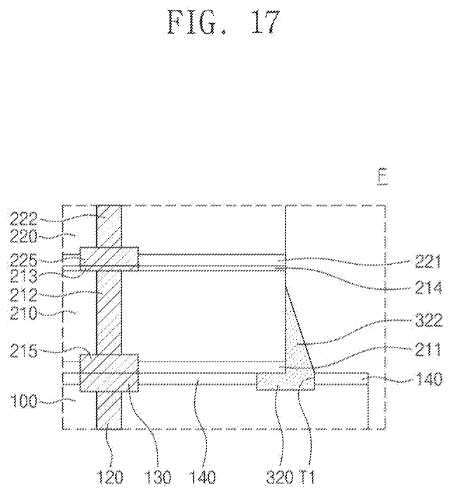

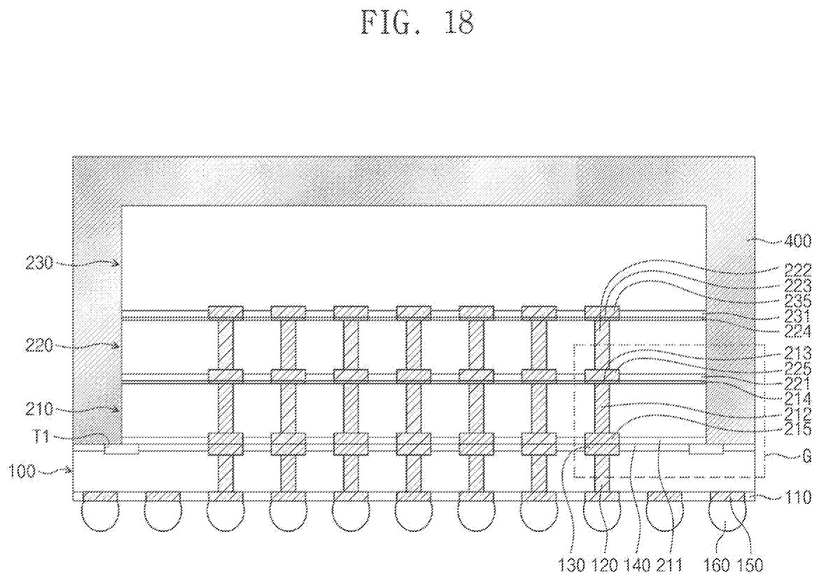

FIG. 18 is a sectional view illustrating a semiconductor package according to some embodiments. FIG. 19 is an enlarged view illustrating a portion ‘G’ of FIG. 18.

Referring to FIGS. 18 and 19, the semiconductor package may further include a mold layer 400. The mold layer 400 may cover the top surface of the buffer semiconductor chip 100. The mold layer 400 may cover the top surface of the buffer semiconductor chip 100 but may not fill the first trench T1. For example, the first trench T1 may be covered with the mold layer 400, and an inner space of the first trench T1 may be filled with the air. A side surface of the mold layer 400 may be aligned to a side surface of the buffer semiconductor chip 100. The mold layer 400 may enclose the chip stack. That is, the mold layer 400 may cover the side surfaces of the lower semiconductor chip 210, the intermediate semiconductor chip 220, and the upper semiconductor chip 230. The mold layer 400 may be formed to cover the lower semiconductor chip 210, the intermediate semiconductor chip 220, and the upper semiconductor chip 230. In other words, the mold layer 400 may be provided to cover a top surface of the upper semiconductor chip 230. In some embodiments, the mold layer 400 may be provided to expose the top surface of the upper semiconductor chip 230, unlike the illustrated example. The mold layer 400 may be formed of or include an insulating material. For example, the mold layer 400 may be formed of or include an epoxy molding compound (EMC).

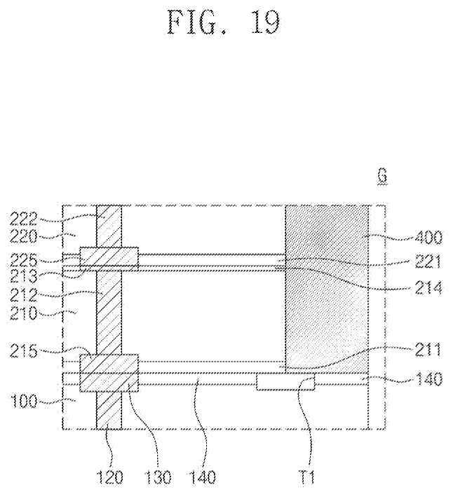

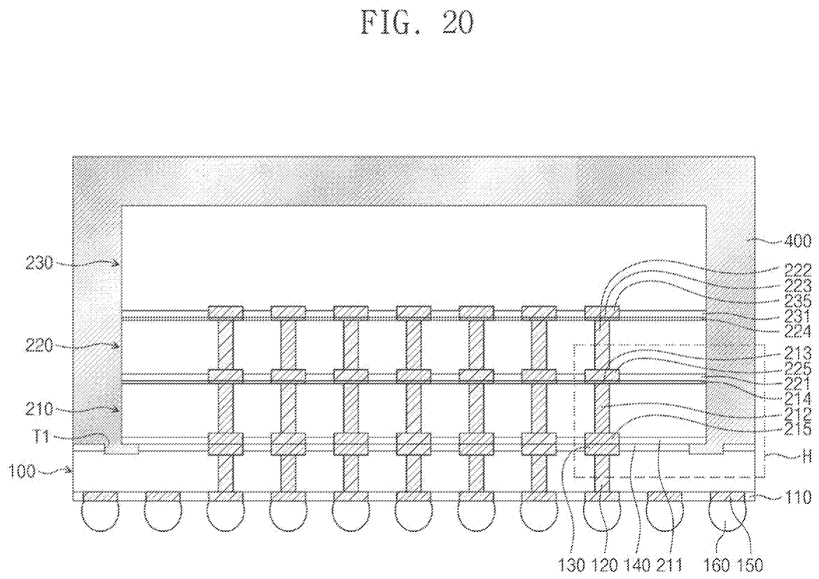

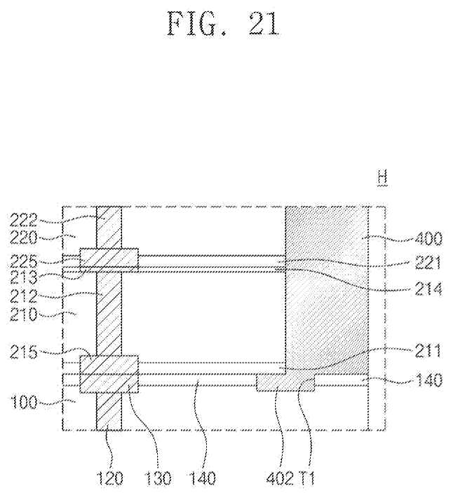

FIG. 20 is a sectional view illustrating a semiconductor package according to some embodiments. FIG. 21 is an enlarged view illustrating a portion ‘H’ of FIG. 20.

Referring to FIGS. 20 and 21, unlike the semiconductor package of FIGS. 18 and 19, the mold layer 400 may be provided to cover the top surface of the buffer semiconductor chip 100 and may extend into the first trench T1. For example, a portion 402 of the mold layer 400 may extend into the first trench T1 and may completely fill the inner space of the first trench T1. The portion 402 of the mold layer 400 in the first trench T1 may support the corner of the lower semiconductor chip 210.

According to some embodiments, the portion 402 of the mold layer 400 may absorb a stress, which is exerted on the buffer semiconductor chip 100 from the corner of the lower semiconductor chip 210. Thus, a pressure or stress from the corner of the lower semiconductor chip 210 may be absorbed by the portion 402 of the mold layer 400 and may not be transferred to the semiconductor layer of the buffer semiconductor chip 100. As a result, the semiconductor layer of the buffer semiconductor chip 100 may not be broken or damaged. Accordingly, it may be possible to realize a semiconductor package with improved structural stability.

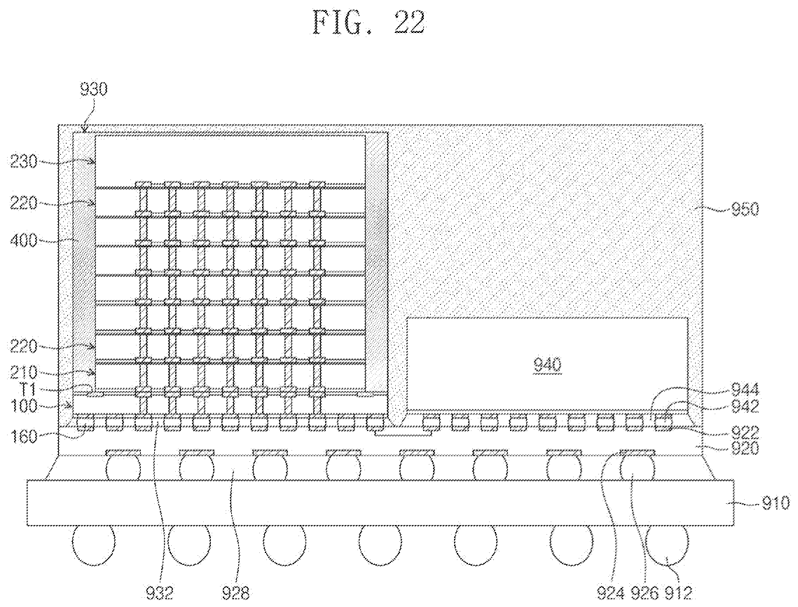

FIG. 22 is a sectional view illustrating a semiconductor module according to some embodiments.

Referring to FIG. 22, the semiconductor module may be, for example, a memory module, which includes a module substrate 910, a chip stack package 930 and a graphics processing unit (GPU) 940, which are mounted on the module substrate 910, and an outer mold layer 950 covering the chip stack package 930 and the graphics processing unit 940. The semiconductor module may further include an interposer 920 provided on the module substrate 910.

The module substrate 910 may be provided. The module substrate 910 may include a printed circuit board (PCB) having signal patterns, which are formed on a top surface thereof.

Module terminals 912 may be disposed below the module substrate 910. The module substrate 910 may include solder balls or solder bumps, and the semiconductor module may be classified into a ball grid array (BGA) type, a fine ball-grid array (FBGA) type, or a land grid array (LGA) type, depending on the kind and structure of the module substrate 910.

The interposer 920 may be provided on the module substrate 910. The interposer 920 may include first substrate pads 922 and second substrate pads 924, which are respectively placed on top and bottom surfaces of the interposer 920 and are exposed to the outside of the interposer 920. The interposer 920 may be configured to provide a redistribution structure for the chip stack package 930 and the graphics processing unit 940. The interposer 920 may be mounted on the module substrate 910 in a flip chip manner. For example, the interposer 920 may be mounted on the module substrate 910 using substrate terminals 926, which are provided on the second substrate pads 924. The substrate terminals 926 may include solder balls or solder bumps. A first under-fill layer 928 may be provided between the module substrate 910 and the interposer 920.

The chip stack package 930 may be disposed on the interposer 920. The chip stack package 930 may have the same or similar structure as the semiconductor package described with reference to FIGS. 1, 2, 3, 4, 5, 6, 7, 8, 9, 10, 11, 12, 13, 14, 15, 16, 17, 18, 19, 20, and 21.

The chip stack package 930 may be mounted on the interposer 920. For example, the chip stack package 930 may be coupled to the first substrate pads 922 of the interposer 920 through the outer terminals 160 of the buffer semiconductor chip 100. A second under-fill layer 932 may be provided between the chip stack package 930 and the interposer 920. The second under-fill layer 932 may be provided to fill a space between the interposer 920 and the buffer semiconductor chip 100 and to enclose the outer terminals 160 of the buffer semiconductor chip 100.

The graphics processing unit 940 may be disposed on the interposer 920. The graphics processing unit 940 may be disposed to be spaced apart from the chip stack package 930. The graphics processing unit 940 may be thicker than the semiconductor chips 100 and 200 of the chip stack package 930. The graphics processing unit 940 may include a logic circuit. In other words, the graphics processing unit 940 may be a logic chip. Bumps 942 may be provided on a bottom surface of the graphics processing unit 940. For example, the graphics processing unit 940 may be coupled to the first substrate pads 922 of the interposer 920 through the bumps 942. A third under-fill layer 944 may be provided between the interposer 920 the graphics processing unit 940. The third under-fill layer 944 may be provided to fill a space between the interposer 920 and the graphics processing unit 940 and to enclose the bumps 942.

The outer mold layer 950 may be provided on the interposer 920. The outer mold layer 950 may cover the top surface of the interposer 920. The outer mold layer 950 may enclose the chip stack package 930 and the graphics processing unit 940. A top surface of the outer mold layer 950 may be located at the same level as a top surface of the chip stack package 930. The outer mold layer 950 may be formed of or include an insulating material. For example, the outer mold layer 950 may be formed of or include an epoxy molding compound (EMC).

FIGS. 23, 24, 25, 26, 27, 28, 29, 30, and 31 are sectional views illustrating a method of fabricating a semiconductor package, according to some embodiments.

Referring to FIG. 23, the buffer semiconductor chip 100 may be formed. The buffer semiconductor chip 100 may be provided to have substantially the same or similar features as the buffer semiconductor chip 100 described with reference to FIGS. 1, 2, 3, 4, 5, 6, 7, 8, 9, 10, 11, 12, 13, 14, 15, 16, 17, 18, 19, 20, 21, and 22. For example, the buffer semiconductor chip 100 may include the first circuit layer 110, which is provided on a surface of the buffer semiconductor chip 100, the first protection layer 140, which is opposite to the first circuit layer 110, the first front pad 150, which is provided on the first circuit layer 110, and the first via 120, which is provided to penetrate the buffer semiconductor chip 100 in a direction from the first protection layer 140 toward the first circuit layer 110. In more detail, the first circuit layer 110 may be formed by forming a transistor or an integrated circuit on a front surface of the buffer semiconductor chip 100, and the first front pad 150, which is connected to the first circuit layer 110, may be formed on the first circuit layer 110. A penetration hole may be formed on a rear surface of the buffer semiconductor chip 100, and then, the first via 120, which is connected to the first circuit layer 110, may be formed by filling the penetration hole with a conductive material. The first protection layer 140 may be formed on the rear surface of the buffer semiconductor chip 100 to cover the first via 120. The surface of the buffer semiconductor chip 100, on which the first circuit layer 110 is provided, may be an active surface of the buffer semiconductor chip 100, and an opposite surface may be an inactive surface of the buffer semiconductor chip 100.

Although not shown, the buffer semiconductor chip 100 may be provided on a carrier substrate. The carrier substrate may be an insulating substrate, which is formed of or includes glass or polymer, or a conductive substrate, which is formed of or includes a metallic material. An adhesive member may be provided on a top surface of the carrier substrate. The buffer semiconductor chip 100 may be attached to the carrier substrate such that the first circuit layer 110 is placed to face the carrier substrate.

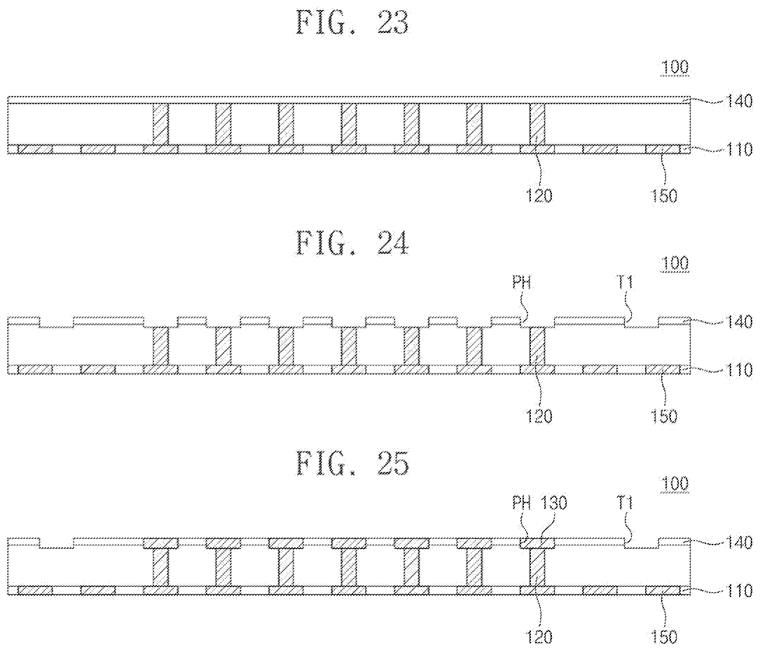

Referring to FIG. 24, the first protection layer 140 may be patterned to form a pad hole PH and the first trench T1. For example, a mask pattern may be formed on the first protection layer 140, and an etching process using the mask pattern as an etch mask may be performed. As a result of the etching process, the pad hole PH and the first trench T1 may penetrate the first protection layer 140 and may extend into the semiconductor layer of the buffer semiconductor chip 100. However, embodiments are not limited to this example, in an embodiment, the pad hole PH and the first trench T1 may not extend into the semiconductor layer of the buffer semiconductor chip 100. The pad hole PH may be formed on a center portion of the buffer semiconductor chip 100, and the first trench T1 may be formed around an outer perimeter of the buffer semiconductor chip 100. The pad hole PH and the first trench T1 may have bottom surfaces that are located at the same level. FIG. 24 illustrates an example, in which the pad hole PH and the first trench T1 are formed at the same time by the same process, but in an embodiment, the pad hole PH and the first trench T1 may be separately formed by different processes. In this case, a level of the bottom surface of the pad hole PH may be located at a level that is different from a level of the bottom surface of the first trench T1.

In an embodiment, not only the first trench T1 but also the second or third trench T2 or T3 (e.g., FIGS. 7 and 8) may be formed during the etching process. In this case, the semiconductor package may be fabricated to have the structure described with reference to FIGS. 7 and 8. The description that follows will be given based on the embodiment of FIG. 24.

Referring to FIG. 25, the first rear pad 130 may be formed in the pad hole PH. For example, a seed layer may be formed to conformally cover the top surface of the first protection layer 140 and an inner side surface and a bottom surface of the pad hole PH, and then, a plating process using the seed layer as a seed may be performed to form a metal layer. Thereafter, the first rear pad 130 may be formed by performing a planarization process on the metal layer to expose the top surface of the first protection layer 140. Here, the metal layer may not fill the first trench T1. For example, a sacrificial layer may be formed to cover the first trench T1, before the forming of the first rear pad 130, and then, the first rear pad 130 may be formed. The sacrificial layer may be removed, after the formation of the first rear pad 130.

In some embodiments, the pad hole PH may be formed in the buffer semiconductor chip 100, the first rear pad 130 may be formed in the pad hole PH, and then, the first trench T1 may be formed by a separate process.

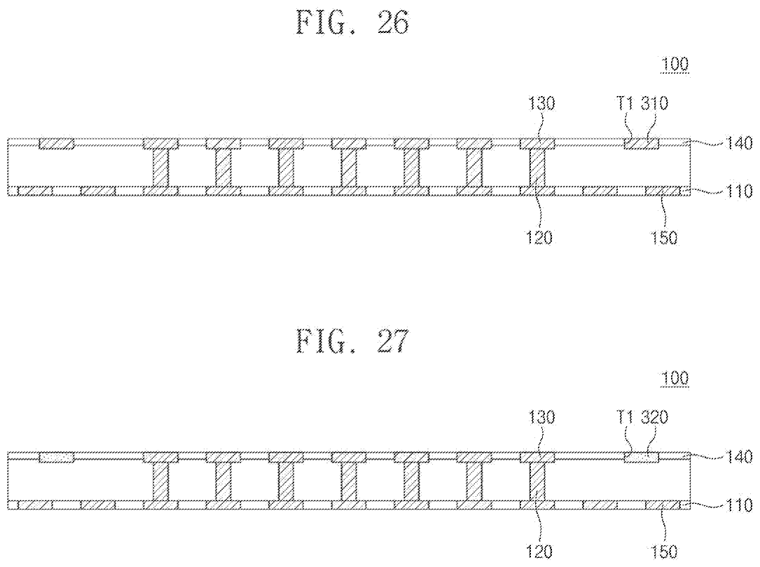

In an embodiment, the first buffering structure 310 may be formed in the first trench T1, as shown in FIG. 26. For example, in the process of forming the first rear pad 130, the seed layer may be formed to conformally the inner side surface and the bottom surface of the pad hole PH and an inner side surface and a bottom surface of the first trench T1, and a metal layer may be formed by performing a plating process using the seed layer as a seed. Thereafter, a planarization process may be performed on the metal layer to expose the top surface of the first protection layer 140, and the first rear pad 130 and the first buffering structure 310 may be respectively formed in the pad hole PH and the first trench T1. In some embodiments, the first rear pad 130 may be formed in the pad hole PH, and then, the first buffering structure 310 may be formed by a separate process. In this case, the semiconductor package may be fabricated to have the structure described with reference to FIGS. 10 and 11.

In an embodiment, the second buffering structure 320 may be formed in the first trench T1, as shown in FIG. 27. For example, the formation of the second buffering structure 320 may include forming the first rear pad 130 in the pad hole PH, forming an insulating layer on the first protection layer 140 to fill the first trench T1, and performing a planarization process on the insulating layer to expose the top surface of the first protection layer 140. In this case, the semiconductor package may be fabricated to have the structure described with reference to FIGS. 14 and 15. The description that follows will be given based on the embodiment of FIG. 25.

Referring to FIG. 28, the lower semiconductor chip 210 may be fabricated. The lower semiconductor chip 210 may be provided to have substantially the same or similar features as the lower semiconductor chip 210 described with reference to FIGS. 1, 2, 3, 4, 5, 6, 7, 8, 9, 10, 11, 12, 13, 14, 15, 16, 17, 18, 19, 20, and 22. For example, the lower semiconductor chip 210 may include the second circuit layer 211, which is provided on a surface of the lower semiconductor chip 210, the second protection layer 214, which is opposite to the second circuit layer 211, the second via 212, which is provided to penetrate the lower semiconductor chip 210 in a direction from the second protection layer 214 toward the second circuit layer 211, the second rear pad 213, which is provided in the second protection layer 214, and the second front pad 215, which is provided on the second circuit layer 211. In more detail, a semiconductor wafer WF may be provided. The second circuit layer 211 may be formed by forming a transistor or an integrated circuit on a front surface of the semiconductor wafer WF, and the second front pads 215, which are connected to the second circuit layer 211, may be formed on the second circuit layer 211. Penetration holes may be formed on a rear surface of the semiconductor wafer WF, and the second vias 212, which are connected to the second circuit layer 211, may be formed by filling the penetration holes with a conductive material. The second protection layer 214 may be formed on the rear surface of the semiconductor wafer WF to cover the second vias 212, and the second rear pads 213, which are connected to the second vias 212, may be formed in the second protection layer 214. The surface of the semiconductor wafer WF, on which the second circuit layer 211 is provided, may be an active surface of the semiconductor wafer WF, and an opposite surface may be an inactive surface of the semiconductor wafer WF. Hereinafter, the lower semiconductor chips 210, which are spaced apart from each other, may be formed by performing a sawing process on the semiconductor wafer WF along a sawing line SL.

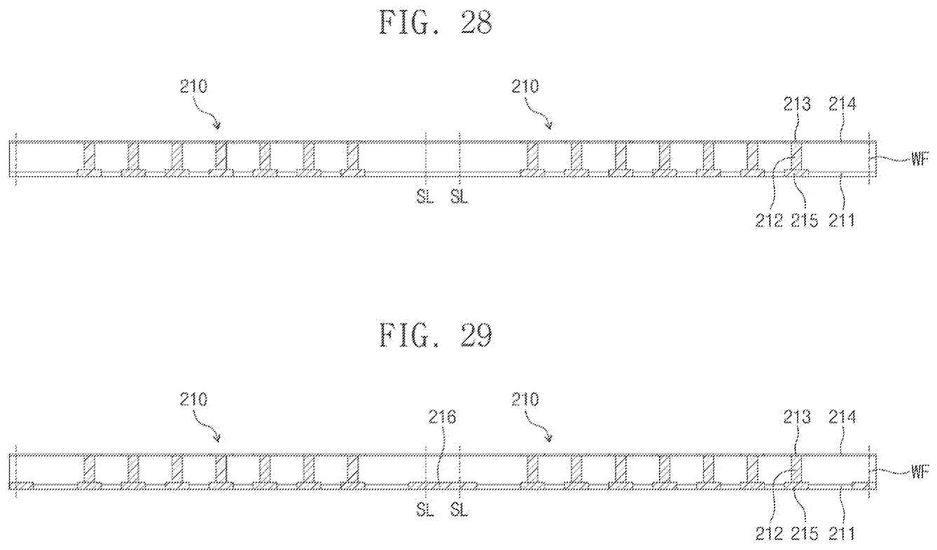

In an embodiment, as shown in FIG. 29, the dummy pads 216 may be formed on the front surface of the semiconductor wafer WF, when the second front pads 215 are formed. Here, the sawing line SL may cross the dummy pads 216. Accordingly, the dummy pads 216 may be cut by the sawing process, and the dummy pads 216 may be formed on the edge or corner of the lower semiconductor chip 210. In this case, the semiconductor package may be fabricated to have the structure described with reference to FIGS. 12 and 13. The description that follows will be given based on the embodiment of FIG. 28.

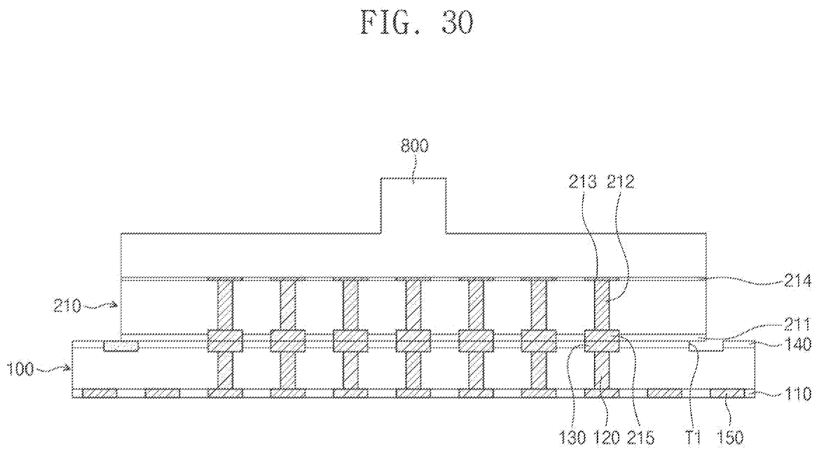

Referring to FIG. 30, the lower semiconductor chip 210 may be bonded to the buffer semiconductor chip 100. The lower semiconductor chip 210 and the buffer semiconductor chip 100 may be bonded to each other in a chip-to-chip shape. The lower semiconductor chip 210 may be disposed on the buffer semiconductor chip 100. For example, an active surface of the lower semiconductor chip 210 may face an inactive surface of the buffer semiconductor chip 100. The lower semiconductor chip 210 may be disposed on the buffer semiconductor chip 100 such that the first rear pad 130 of the buffer semiconductor chip 100 is vertically aligned to the second front pad 215 of the lower semiconductor chip 210. Here, an edge or corner of the lower semiconductor chip 210 may be placed on the first trench T1 of the buffer semiconductor chip 100.

A thermal treatment process may be performed on the buffer semiconductor chip 100 and the lower semiconductor chip 210. As a result of the thermal treatment process, the first rear pad 130 and the second front pad 215 may be bonded to each other. For example, the first rear pad 130 and the second front pad 215 may be bonded to each other such that, after bonding, the first rear pad 130 and the second front pad 215 form a single object. The bonding of the first rear pad 130 and the second front pad 215 may be achieved in a natural manner. In detail, the first rear pad 130 and the second front pad 215 may be formed of the same material (e.g., copper (Cu)), and in this case, the first rear pad 130 and the second front pad 215 may be bonded to each other by a surface activation phenomenon at an interface of the first rear pad 130 and the second front pad 215, which are in contact with each other, or by the consequent metal-to-metal hybrid bonding process. The first protection layer 140 may be bonded to the insulating pattern of the second circuit layer 211 by the thermal treatment process. The lower semiconductor chip 210 may be pressed toward the buffer semiconductor chip 100, and this may make it possible to facilitate the process of bonding the lower semiconductor chip 210 to the buffer semiconductor chip 100. For example, a bonding tool 800 may be configured to exert a pressure on the lower semiconductor chip 210 in a direction toward the buffer semiconductor chip 100.

In the process of bonding the lower semiconductor chip 210 to the buffer semiconductor chip 100, a pressure and stress, which is exerted on the buffer semiconductor chip 100 by chip stack may be strong and a pressure and stress, which is exerted on the buffer semiconductor chip 100 by the lower semiconductor chip 210, may be strongest at an edge portion (e.g., the corner) of the lower semiconductor chip 210. In particular, the lower semiconductor chip 210 and the buffer semiconductor chip 100 may be bent by a thermal treatment step involved in the bonding process, and in this case, the pressure and stress, which is exerted on the buffer semiconductor chip 100 by the lower semiconductor chip 210, may be strongest at the corner of the lower semiconductor chip 210.

According to some embodiments, the first trench T1 may be formed in the buffer semiconductor chip 100, and the corner of the lower semiconductor chip 210 may be spaced apart from the buffer semiconductor chip 100 by the first trench T1. Thus, it may be possible to prevent the buffer semiconductor chip 100 from being damaged by a pressure and stress exerted through the corner of the lower semiconductor chip 210. This may make it possible to reduce a failure in a process of fabricating a semiconductor package.

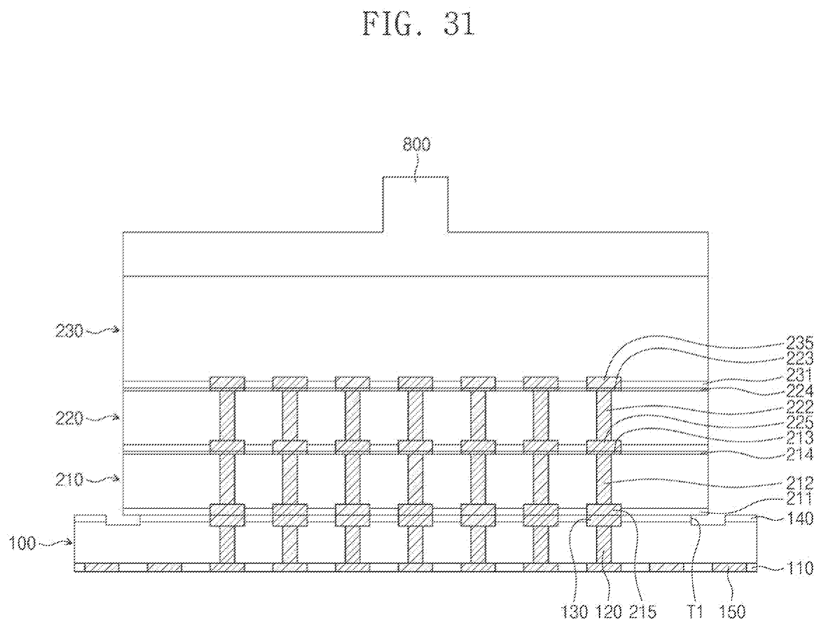

Referring to FIG. 31, the intermediate and upper semiconductor chips 220 and 230 may be stacked on the lower semiconductor chip 210. For example, the intermediate semiconductor chip 220 may be bonded to the top surface of the lower semiconductor chip 210, and the upper semiconductor chip 230 may be bonded to the top surface of the intermediate semiconductor chip 220. The processes of bonding the intermediate and upper semiconductor chips 220 and 230 may be performed in the same or similar manner as the process of bonding the lower semiconductor chip 210.

The intermediate and upper semiconductor chips 220 and 230 may be bent by heat, which is supplied during the bonding process of the intermediate and upper semiconductor chips 220 and 230 or a subsequent thermal treatment process. As the number of the semiconductor chips 210, 220, and 230 stacked on the buffer semiconductor chip 100 is increased, a pressure and stress, which is exerted on the buffer semiconductor chip 100 by the lower semiconductor chip 210, may be increased.

According to some embodiments, it may be possible to prevent the buffer semiconductor chip 100 from being damaged by the pressure and stress exerted from the corner of the lower semiconductor chip 210. This prevention may make it possible to reduce a failure in a process of fabricating a semiconductor package.

According to some embodiments, a semiconductor package may include a trench, which is formed in a top surface of a buffer semiconductor chip and is overlapped with a corner of a lower semiconductor chip. The corner of the lower semiconductor chip may be spaced apart from the buffer semiconductor chip by the trench. Thus, it may be possible to prevent the buffer semiconductor chip from being damaged by a stress, which is exerted by a chip stack (in particular, the lower semiconductor chip). In other words, it may be possible to improve structural stability of the semiconductor package.

In addition, a buffering structure may be provided in the trench of the buffer semiconductor chip to absorb a stress, which is exerted on the buffer semiconductor chip by the corner of the lower semiconductor chip. Thus, a pressure or stress by the corner of the lower semiconductor chip may be absorbed by the buffering structure and may not be transferred to a semiconductor layer of the buffer semiconductor chip. In other words, the semiconductor layer of the buffer semiconductor chip may not be broken or damaged. In addition, the corner of the lower semiconductor chip may be supported by the buffering structure. Accordingly, it may be possible to realize a semiconductor package with improved structural stability.

In a method of fabricating a semiconductor package according to some embodiments, the trench may be formed in the buffer semiconductor chip, and the corner of the lower semiconductor chip may be spaced apart from the buffer semiconductor chip by the trench. Thus, it may be possible to prevent the buffer semiconductor chip from being damaged by a pressure and stress exerted through or by the corner of the lower semiconductor chip. This may make it possible to reduce a failure in a process of fabricating a semiconductor package.

While aspects of example embodiments have been particularly shown and described, it will be understood that variations in form and detail may be made therein without departing from the spirit and scope of the following claims.

1. A semiconductor package comprising:
a substrate comprising a substrate pad and a plurality of vias, the substrate having a first trench on a top surface of the substrate; and
a chip stack on the substrate, the chip stack comprising a plurality of semiconductor chips,
wherein a chip pad of a first semiconductor chip, which is a lowermost one of the plurality of semiconductor chips, is bonded to the substrate pad of the substrate,
wherein the chip pad and the substrate pad are formed of a same metallic material, and
wherein the first trench overlaps with a corner of the first semiconductor chip, when viewed in plan view.

2. The semiconductor package of claim 1, wherein the corner of the first semiconductor chip is vertically spaced apart from the substrate.

3. The semiconductor package of claim 1, wherein, when viewed in plan view, a first portion of the first trench overlaps with the first semiconductor chip, and a second portion of the first trench other than the first portion is located outside a side surface of the first semiconductor chip.

4. The semiconductor package of claim 1, wherein the first trench has a circular, rectangular, square, polygonal, or cross shape, when viewed in plan view.

5. The semiconductor package of claim 1, wherein:
the first semiconductor chip has a first side surface and a second side surface adjacent to the first side surface,
the corner of the first semiconductor chip is a corner at which the first side surface and the second side surface meet, and
the first trench is located below the corner and extends along the first side surface and the second side surface.

6. The semiconductor package of claim 5, wherein the first trench surrounds the first semiconductor chip, when viewed in plan view.

7. The semiconductor package of claim 1, wherein the substrate further comprises a second trench is in the top surface of the substrate, the second trench being spaced apart from the first trench,
wherein a first side surface of the first semiconductor chip is in contact with the corner,
wherein the second trench extends along the first side surface of the first semiconductor chip, and
wherein the second trench overlaps the first side surface of the first semiconductor chip, when viewed in plan view.

8. (canceled)

9. The semiconductor package of claim 1, wherein the substrate further comprises a third trench in the top surface of the substrate, the third trench being spaced apart from the first trench,
wherein the third trench is adjacent to the corner, and
wherein an entirety of the third trench overlaps with the first semiconductor chip, when viewed in plan view.

10-11. (canceled)

12. The semiconductor package of claim 1, wherein the substrate further comprises a first buffering structure in the first trench,
wherein the first buffering structure comprises a metallic material, and
wherein a top surface of the first buffering structure is substantially flat and is substantially coplanar with the top surface of the substrate.

13. The semiconductor package of claim 12, wherein the first buffering structure is at the same level as the substrate pad, and
wherein the first buffering structure has substantially the same thickness as the substrate pad.

14. (canceled)

15. The semiconductor package of claim 12, wherein the substrate further comprises a second buffering structure in the first trench,
wherein the second buffering structure comprises an insulating material, and
wherein a rigidity of the second buffering structure is less than a rigidity of the substrate.

16. (canceled)

17. The semiconductor package of claim 1, further comprising a mold layer on the substrate that encloses the chip stack,
wherein the mold layer extends into the first trench.

18. The semiconductor package of claim 1, wherein a bottom surface of the first semiconductor chip and a bottom surface of the chip pad are substantially flat and are substantially coplanar with each other,
wherein the top surface of the substrate and a top surface of the substrate pad are substantially flat and are substantially coplanar with each other, and
wherein the bottom surface of the first semiconductor chip is in direct contact with the top surface of the substrate.

19. (canceled)

20. A semiconductor package comprising:
a buffer chip;
a first semiconductor chip on the buffer chip, a first pad of the buffer chip being bonded to a second pad of the first semiconductor chip, the first pad and the second pad being formed of a same metallic material;
a second semiconductor chip on the first semiconductor chip, a third pad of the first semiconductor chip being bonded to a fourth pad of the second semiconductor chip, the third pad and the fourth pad being formed of a same metallic material;
a mold layer on the buffer chip that encloses the first semiconductor chip and the second semiconductor chip; and
a buffering structure interposed between the buffer chip and the first semiconductor chip,
wherein the buffering structure overlaps with a corner of the first semiconductor chip, when viewed in plan view.

21. The semiconductor package of claim 20, wherein the buffering structure is buried in an upper portion of the buffer chip and is in contact with a bottom surface of the first semiconductor chip.

22. The semiconductor package of claim 21, wherein a top surface of the buffering structure is substantially flat and is substantially coplanar with a top surface of the buffer chip.

23-24. (canceled)

25. The semiconductor package of claim 20, wherein the buffer chip comprises a first trench in a top surface of the buffer chip,
wherein the first trench overlaps with the corner of the first semiconductor chip, when viewed in plan view, and
wherein the buffering structure is in the first trench.

26. The semiconductor package of claim 20, wherein the corner of the first semiconductor chip is vertically spaced apart from the buffer chip.

27-28. (canceled)

29. The semiconductor package of claim 28, wherein the buffering structure is located at the same level as the first pad, and
wherein the buffering structure has substantially the same thickness as the first pad.

30-31. (canceled)

32. A semiconductor package comprising:
a semiconductor substrate comprising a plurality of vias;
a plurality of semiconductor chips stacked on the semiconductor substrate; and
a mold layer on the semiconductor substrate that encloses the plurality of semiconductor chips,
wherein the semiconductor substrate comprises:
a first trench in a top surface of the semiconductor substrate; and
a first buffering structure in the first trench,
wherein the first trench overlaps with a corner of a lowermost one of the plurality of semiconductor chips, when viewed in plan view, and
wherein a rigidity of the first buffering structure is less than a rigidity of the semiconductor substrate.

33-46. (canceled)
